(19) United States
(12) Patent Application Publication
(10) Pub. No.: US 2025/0201671 A1
(43) Pub. Date: Jun. 19, 2025

(54) METAL-FILLED CONTACT HOLE IN MICRO-FABRICATED DEVICE

(71) Applicant: Infineon Technologies AG, Neubiberg (DE)

(72) Inventors: Matthias German Dietl, Villach (AT); Alexander Zesar, Villach (AT); Stefan Woehlert, Villach (AT); Anita Maria Satz, Villach (AT)

(21) Appl. No.: 18/973,797

(22) Filed: Dec. 9, 2024

(30) Foreign Application Priority Data
Dec. 13, 2023 (DE) 102023134996.1

(51) Int. Cl. H01L 23/48; H01L 21/768; H01L 23/528

(52) U.S. Cl. CPC H01L 23/481; H01L 21/76828; H01L 21/76864; H01L 23/5283

(57) ABSTRACT

A metal-filled contact hole is generated in micro-fabrication technology by forming a first metal layer over a substrate and a first interface metal layer over the first metal layer. A metal of the first interface metal layer is different from a metal of the first metal layer. A dielectric layer is formed over the first interface metal layer. A contact hole is formed in the dielectric layer. A second interface metal layer is formed over the first interface metal layer after forming the contact hole. A second metal layer is formed over the second interface metal layer. A metal of the second interface metal layer is different from a metal of the second metal layer. The substrate is annealed, such that an oxide layer previously formed on the first interface metal layer in a period between the formation of the first and second interface metal layers is diluted by diffusion.

### TECHNICAL FIELD

This disclosure relates generally to micro-fabrication technology, and in particular to techniques of generating metal-filled contact holes in micro-fabricated devices.

### BACKGROUND

Multi-metal layer stacks are used as standard in microfabrication technology. In such multi-metal layer stacks, individual metal layers are electrically connected by metal-filled contact holes, so-called vias.

To create a via, a dielectric layer is deposited on a first metal (M1) layer and structured to form a hole. Subsequently, another metal (M2) layer is deposited and a contact junction is formed between M1 and M2 through the hole.

A common problem with this process is the formation of native oxide on M1 before M2 is deposited. Typically, this problem is solved by back-sputtering. This involves in situ ion milling with argon ions prior to deposition of M2 to remove the native oxide on M1 before M2 is deposited.

### SUMMARY

According to an aspect of the disclosure, a method of generating a metal-filled contact hole in micro-fabrication technology includes forming a first metal layer over a substrate. A first interface metal layer is formed over the first metal layer, wherein the metal of the first interface metal layer is different from the metal of the first metal layer. A dielectric layer is formed over the first interface metal layer. A contact hole is formed in the dielectric layer. A second interface metal layer is formed over the first interface metal layer after forming the contact hole. A second metal layer is formed over the second interface metal layer, wherein the metal of the second interface metal layer is different from the metal of the second metal layer. The substrate is annealed, whereby an oxide layer that was formed on the first interface metal layer in a period between the formation of the first interface metal layer and the second interface metal layer is diluted by diffusion.

According to a further aspect of the disclosure, a method of manufacturing a micro-fabricated device comprises providing a wafer substrate; forming alternating metal layers and dielectric layers over the wafer substrate; generating a plurality of metal-filled contact holes between at least two metal layers separated by at least one dielectric layer according to the method recited above; and dicing the wafer substrate to singulate the micro-fabricated device.

According to still a further aspect of the disclosure, a micro-fabricated device comprises a substrate; a first metal layer disposed over the substrate; a first interface metal layer disposed over the first metal layer, wherein the metal of the first interface metal layer is different from the metal of the first metal layer; a dielectric layer disposed over the first interface metal layer; a contact hole in the dielectric layer; a second metal layer disposed over the dielectric layer and reaching into the contact hole, wherein, in the contact hole, a second interface metal layer is disposed over the first interface metal layer, wherein the second metal layer is electrically connected to the second interface metal layer and the metal of the second interface metal layer is different from the metal of the second metal layer; and a diffusion-diluted oxide layer located between the first interface metal layer and the second interface metal layer.

### BRIEF DESCRIPTION OF THE DRAWINGS

In the drawings, like reference numerals designate corresponding similar parts. The features of the various illustrated embodiments can be combined unless they exclude each other and/or can be selectively omitted if not described to be necessarily required. Embodiments are depicted in the drawings and are exemplarily detailed in the description which follows.

FIG. 1 is a schematic cross-sectional view of an example of a contact hole in a micro-fabricated device.

FIG. 2 is a flowchart illustrating stages of an exemplary method of generating a metal-filled contact hole in micro-fabrication technology.

FIG. 3 illustrates an example of a layer stack used in a contact hole of FIG. 1.

FIG. 4 illustrates examples A to D of layer stacks used in contact holes of FIG. 1.

FIG. 5A is a plan view of a test structure for measuring the electrical resistance of metal-filled contact holes.

FIG. 5B is a diagram illustrating electrical resistance values of metal-filled contact holes measured by the test structure of FIG. 5A for layer stack examples A to D (FIG. 4) produced by different manufacturing processes, and for an example X of a conventional layer stack using a standard back-sputtering process for oxide removal.

FIG. 6A is a transmission electron microscope (TEM) cross section image of an edge portion of an exemplary contact hole using a layer stack in accordance with example C of FIG. 4.

FIG. 6B is an energy dispersive X-ray spectroscopy (EDX) analysis cross section image showing the oxygen concentration in the exemplary contact hole of FIG. 6A.

FIG. 6C is an EDX analysis cross section image showing the titanium concentration in the exemplary contact hole of FIG. 6A.

FIG. 7A is a TEM cross section image of an edge portion of an exemplary contact hole using a layer stack in accordance with example B of FIG. 4.

FIG. 7B is an EDX analysis cross section image showing the oxygen concentration in the exemplary contact hole of FIG. 7A.

FIG. 7C is an EDX analysis cross section image showing the titanium concentration in the exemplary contact hole of FIG. 7A.

FIG. 8 is a graph illustration the concentration of aluminum, titanium and oxygen (in cps: counts per second) obtained by EDX analysis along a longitudinal cross section of the contact hole of FIGS. 7A-7C (i.e., example B of FIG. 4).

FIG. 9 is a schematic cross-sectional view of an example of a micro-fabricated device containing a contact hole and an optical active area.

### DETAILED DESCRIPTION

It is to be understood that the features of the various exemplary embodiments and examples described herein may be combined with each other unless specifically noted otherwise.

As used in this specification, the terms “electrically connected” or “electrically coupled” or similar terms are not meant to mean that the elements are directly contacted together; intervening elements may be provided between the “electrically connected” or “electrically coupled” elements, respectively. However, in accordance with the disclosure, the above-mentioned and similar terms may, optionally, also have the specific meaning that the elements are directly contacted together, i.e. that no intervening elements are provided between the “electrically connected” or “electrically coupled” elements, respectively.

Further, the words “over” or “beneath” or similar terms with regard to a part, element or material layer formed or located or arranged “over” or “beneath” a surface may be used herein to mean that the part, element or material layer be located (e.g. placed, formed, arranged, deposited, etc.)

“directly on” or “directly under”, e.g. in direct contact with, the implied surface. The word “over” or “beneath” or similar terms used with regard to a part, element or material layer formed or located or arranged “over” or “beneath” a surface may, however, either be used herein to mean that the part, element or material layer be located (e.g. placed, formed, arranged, deposited, etc.) “indirectly on” or “indirectly under” the implied surface, with one or more additional parts, elements or layers being arranged between the implied surface and the part, element or material layer.

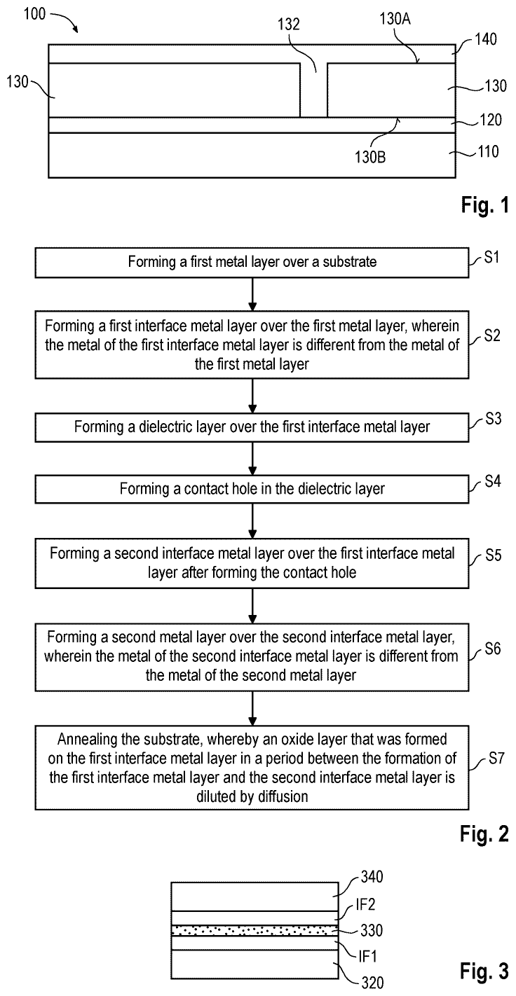

Referring to FIG. 1, a micro-fabricated device 100 includes a substrate 110. A first metal (M1) layer 120 is disposed over the substrate 110. A dielectric layer 130 is disposed over the M1 layer. The dielectric layer 130 is an electrically insulating layer.

The dielectric layer 130 contains a contact hole 132. The contact hole 132 may be a through-hole, i.e. may open to an upper surface 130A and a lower surface 130B of the dielectric layer 130.

The micro-fabricated device 100 further includes a second metal (M2) layer 140. The M2 layer 140 is disposed over the dielectric layer 130 and may, e.g., reach into the contact hole 132. The contact hole 132 allows electrical contact between the M1 layer 120 and the M2 layer 140.

The M1 layer 120 and the M2 layer 140 can be any two sequential metal layers in the micro-fabricated device 100. It is also possible that the M1 layer 120 and the M2 layer 140 are two non-sequential metal layers, i.e. that one or a plurality of further metal layers (not shown) are arranged between the M1 layer 120 and the M2 layer 140. For example, the micro-fabricated device 100 may include a layer stack of N metal layers 120, 140, with each sequential metal layers 120, 140 being separated by an intermediate dielectric layer 130, wherein the M1 layer 120 is any of the N−1 metal layers and the M2 layer 140 is any of the metal layers above the M1 layer 120 (N is an integer equal to or greater than 2).

The substrate 110 may be any substrate which can be used to carry a multi-metal layer stack in micro-fabrication technology. For example, the substrate 110 may comprise or be of a semiconductor material such as, e.g., Si, SiC, SiGe, Ge, GaN, GaAs, InAs, etc., and other compound semiconductors. In particular, a semiconductor substrate 110 may be made of a WBG (Wide Bandgap) semiconductor material such as, e.g., SiC, GaN, and many III-V and II-VI compound semiconductors having a high bandgap.

If the substrate 110 comprises or is of a semiconductor material, an integrated circuit may, e.g., be provided in the semiconductor material. In this case, the M1 layer 120 and the M2 layer 140 may serve as wiring layers for the integrated circuit.

In other examples the substrate 110 may comprise or be of a dielectric insulator material such as, e.g., sapphire or glass. In this case, the substrate 110 does not contain integrated circuits. However, electrical circuits such as, e.g., superconducting circuits may be implemented over the substrate 110. For example, superconducting circuits may contain Josephson junctions. Devices containing Josephson junctions are quantum computers, traveling wave parametric amplifiers (TWPAs) or single flux quantum (SFQ) logic devices, for example.

Other examples for micro-fabricated devices 100 using a substrate 110 which may but need not to be a semiconductor are ion traps used, e.g., as quantum computers. Such ion traps typically contain RF and DC trap electrodes structured out of a M2 layer and a high number of optical elements such as, e.g., optical waveguides, gratings, lenses, mirrors, etc., disposed over the substrate 110.

M1 and/or M2 comprises or is of an electrically conducting material such as, e.g., Al, AlSiCu, AlCu, Cu or any alloy based on these materials. An exemplary AlSiCu alloy may, e.g., have a chemical composition in percent by weight of 98.5% wt of Al, 1.0% wt of Si and 0.5% wt of Cu, balance incidental impurities. An exemplary AlCu alloy may, e.g., have a chemical composition in percent by weight of 99.5% wt of Al and 0.5% wt of Cu, balance incidental impurities. These materials are widely used in microfabrication technology. In other examples, M1 and M2 can comprise or be of Au or Ag or any combination of the above-mentioned materials. Further, M1 and M2 may be different metal materials or may be the same metal materials.

The material of the dielectric layer 130 is an electrically insulating material. It may, e.g., be or comprise an inorganic dielectric layer (such as, e.g., a hard passivation layer). The material of the dielectric layer 130 may, e.g., comprise or be selected from the group consisting of silicon oxide, silicon nitride, silicon oxynitride and intrinsic silicon. For example, the dielectric material may include or be silicon oxide produced by thermal decomposition of tetraethyl orthosilicate (TEOS).

In a conventional process of fabricating a metal-filled contact hole 132, a native oxide is formed on the upper surface of the M1 layer 120 before M2 is deposited. To avoid low electrical conductivity, the native oxide is removed by back-sputtering. Back-sputtering, also known as sputter-etching, may involve in situ ion milling with argon ions prior to deposition of M2. For example, the top 15 to 20 nm of material is removed, and accordingly, the native oxide on M1 is removed.

For contact holes 132 with a certain aspect ratio, e.g. greater than 3:1, oxide removal by back-sputtering is no longer effective enough to ensure through-hole plating with high electrical conductivity. Further, the back-sputtering process typically affects the entire substrate 110 (e.g., wafer). Therefore, optical active areas over the substrate 110 may be impaired by back-sputtering. While the removal of the top 15 to 20 nm of material may not necessarily impose a problem to all structures on a substrate 110, optical elements and/or optical active areas are specifically sensitive to thickness variations and/or surface modifications as caused by back-sputtering.

FIG. 2 is a flowchart illustrating stages of an exemplary method of generating a metal-filled contact hole 132 in micro-fabrication technology. Reference is also made to FIG. 3 illustrating a layer stack used in a contact hole 132.

At S1 a M1 layer 120 is formed over a substrate 110. Any techniques of metal layer formation such as, e.g., PVD (physical vapor deposition) may be used.

At S2 a first interface metal layer IF1 is formed over the M1 layer 120. The metal of the first interface metal layer IF1 is different from the metal of the M1 layer 120.

The M1 layer 120 and the first interface metal layer IF1 may be formed in situ, i.e. without breaking a vacuum in the deposition equipment.

Subsequently, the M1 layer 120 and the first interface metal layer IF1 may (optionally) be structured. Structuring of the M1 layer 120 and the interface metal layer IF1 may be performed by lithography including, e.g., photoresist application, alignment of mask, exposure, photoresist developing, etching, and photoresist removal. Other structuring methods such as, e.g., laser structuring may also be used. As a result, a wiring pattern may be formed. However, it is also possible to proceed without structuring the M1 layer 120 and the first interface metal layer IF1, i.e., to proceed with a continuous unstructured M1 layer 120 and first interface metal layer IF1.

At S3 a dielectric layer 130 is formed over the first interface metal layer IF1. The dielectric layer 130 may, e.g., be of any of the materials mentioned above. Any suitable process of forming the dielectric layer 130 may be used.

At S4 the contact hole 132 is formed in the dielectric layer 130. The contact hole 132 may be formed by lithography. For example, lithography may include photoresist application, alignment of mask, exposure, photoresist developing, etching the contact hole into the dielectric layer, and photoresist removal.

An oxide layer 330 is formed on the first interface metal layer IF1. In some examples, the oxide layer 330 is a native oxide layer which is formed by exposing the substrate 110 with the M1 layer 120 and the first interface metal layer IF1 to atmosphere before or during structuring the M1 layer 120 and the first interface metal layer IF1. Then, by forming the contact hole 132, the (native) oxide layer 330 on the first interface metal layer IF1 may be exposed. Generally, the oxide layer 330 is formed on the first interface metal layer IF1 in a period between the formation of the first interface metal layer IF1 and a second interface metal layer IF2.

At S5 the second interface metal layer IF2 is formed over the first interface metal layer IF1 after forming the contact hole 132. As mentioned, a (native) oxide layer 330 was formed on the first interface metal layer IF1 in a period between the formation of the first interface metal layer IF1 and the second interface metal layer IF2. The (native) oxide layer 330 is, e.g., completely covered by the second interface metal layer IF2 in the contact hole 132.

At S6 the M2 layer 140 is formed over the second interface metal layer IF2. The metal of the M2 layer 140 is different from the metal of the second interface metal layer IF2.

At S7 the substrate 110 is annealed. Thereby, the (native) oxide layer 330, formed on the first interface metal layer IF1, is diluted and/or expanded by diffusion. The dilution/expansion of the (native) oxide layer 330 significantly reduces the electrical resistance in the metal-filled contact hole 132.

In other words, the metal-filled contact hole 132 can be fabricated without removal of the oxide (which may, e.g., be a partly or completely native oxide). Rather, the process relies on the formation of the oxide on the first interface metal layer IF1 (i.e., not on M1) and on the “weakening” or “dissolving” of this oxide layer 330 in the metal(s) of the first and second interface metal layers IF1, IF2 by annealing the substrate 110.

In particular, it is not necessary to subject the oxide layer 330 to a process of back-sputtering as described above.

The metal of the first interface metal layer IF1 may, e.g., comprise or be Ti or a Ti-based alloy. It has been found that Ti forms a thinner and more reactive native oxide compared to the native oxide formed on typical metals (e.g., aluminum) of M1. This native oxide (e.g., titanium oxide) can be dissolved by diffusion into the adjacent first and second interface metal layers IF1, IF2.

The metal of the second interface metal layer IF2 may, e.g., comprise or be Ti or a Ti-based alloy. In some examples, the metal of the second interface metal layer IF2 may be the same as the metal of the first interface metal layer IF1. In other examples, different metals may be used for the first and second interface metal layer IF1, IF2.

FIG. 3 illustrates an example of a metal-filled contact hole before annealing the substrate 110. The metal-filled contact hole contains the first interface metal layer IF1, the second interface metal layer IF2 and the oxide layer 330 disposed between. The first interface metal layer IF1 and the second interface metal layer IF2 may directly contact the oxide layer 330.

The metal-filled contact hole may further include a base metal layer 320 arranged beneath the first interface metal layer IF1 and a top metal layer 340 arranged above the second interface metal layer IF2. The base metal layer 320 may, e.g., be a part of the M1 layer 120 or may be any electrically conductive structure disposed between the M1 layer 120 and the first interface metal layer IF1. Analogously, the top metal layer 340 may, e.g., be a part of the M2 layer 140 or may be any electrically conductive structure disposed between the M2 layer 140 and the second interface metal layer IF2.

In other words, the IF1-330-IF2 interface electrically connects the M1 layer 120 to the M2 layer 140 either directly or via arbitrary electrical structures, which may, e.g., contain one or more barrier layers, etc.

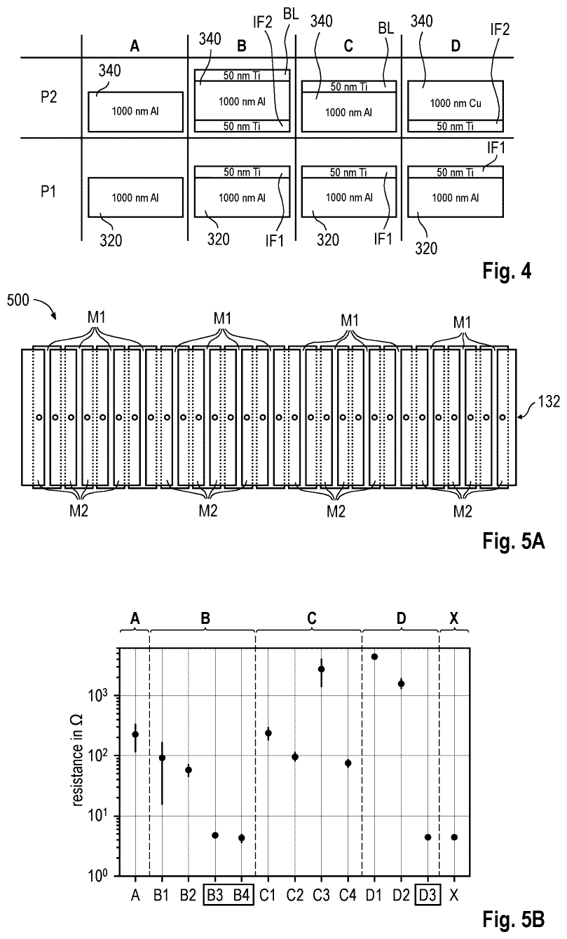

FIG. 4 illustrates examples A to D of layer stacks used in contact holes 132 of FIG. 1. The layer stacks at P1 illustrate the layers formed before formation of the oxide layer 330 (e.g., before exposing the structure to atmosphere and formation of the native oxide 330 on the exposed surface of the layer stacks at P1). The layer stacks at P2 illustrate the metal layers applied after the oxide layer 330 has been formed on the layer stacks at P1 (e.g., after the layer stacks at P1 were exposed to atmosphere and/or oxygen). The oxide layer 330 is not shown in FIG. 4.

In example A, a conventional layer stack is shown. The layer stack A includes a base metal layer 320 (e.g., M1) at P1 and a top metal layer 340 (e.g., M2) at P2. In the example shown, the base metal layer 320 and the top metal layer 340 are of aluminum.

In example B, the layer stack at P1 includes a base metal layer 320 of aluminum and a first interface metal layer IF1 of titanium. The layer stack at P2 includes a second interface metal layer IF2 of titanium and a top metal layer 340 of aluminum. Further, a barrier layer BL of, e.g., titanium is disposed over the top metal layer 340.

In example C, the layer stack at P1 is identical with the layer stack at P1 of example B. The layer stack at P2 includes the top metal layer 340 and the barrier layer BL. However, the layer stack at P2 does not include a second interface metal layer IF2.

In example D, the layer stack at P1 is identical with the layer stack at P1 of examples B and C. The layer stack at P2 includes the top metal layer 340 and the second interface metal layer IF2. The top metal layer 340 is, e.g., made of Cu (and not Al, as in examples A, B and C).

In the examples of FIG. 4, the layer thickness of the base metal layers 320 is 1000 nm. The layer thickness of the top metal layers 340 is 1000 nm. The layer thickness of the first interface metal layers IF1 is 50 nm. The layer thickness of the second interface metal layers IF2 is 50 nm. The layer thickness of the barrier layer BL is 50 nm.

In example A, the native oxide layer 330 is aluminum oxide. In examples B, C and D, the native oxide layer 330 is titanium oxide.

Table 1 illustrates layer stack examples and processes used for preparation. Examples A, B1-4, C1-4, D1-3, X relate to the layer stack examples A, B, C, D and A of FIG. 4, respectively.

TABLE 1
Examples of Layer Stacks and Manufacturing Processes

| | | | reactive | | |
|---|---|---|---|---|---|
| | | | H ion | | back- |
| Examples | P1 | P2 | etching | annealing | sputtering |
| A | Al | Al | | | |
| B1 | Al—Ti | Ti—Al—Ti | | | |
| B2 | Al—Ti | Ti—Al—Ti | x | | |
| B3 | Al—Ti | Ti—Al—Ti | | x | |
| B4 | Al—Ti | Ti—Al—Ti | x | x | |
| C1 | Al—Ti | Al—Ti | | | |
| C2 | Al—Ti | Al—Ti | x | | |
| C3 | Al—Ti | Al—Ti | | x | |
| C4 | Al—Ti | Al—Ti | x | x | |
| D1 | Al—Ti | Ti—Cu—Ti | | | |
| D2 | Al—Ti | Ti—Cu—Ti | x | | |
| D3 | Al—Ti | Ti—Cu—Ti | x | x | |
| X | Al | Al | | | x |

FIG. 5A shows a plan view of a test structure 500 for measuring the electrical resistance of metal-filled contact holes 132, which are designed according to examples A to D of FIG. 4. The test structure 500 consists of 15 metal rectangles in M1 and 16 metal rectangles in M2. The rectangles partially overlap and are connected by metal-filled contact holes 132. Each metal-filled contact hole 132 has a diameter of 2.5 μm. In total, 30 metal-filled contact holes 132 were measures in series. The dielectric layer between M1 and M2 is not shown. M1 (corresponding to the base metal layer 320 in FIG. 4) had a thickness of 1000 nm, M2 (corresponding to the top layer 340 of FIG. 4) had a thickness of 1000 nm and the intermediate dielectric layer 130 (not shown) had a thickness of 1000 nm.

FIG. 5B shows the results of the electrical resistance measurements. The electrical resistance was measured at room temperature. For each example A, B1-4, C1-4, D1-3 and X, two wafers with ten test structures 500 each were measured. The error bars in FIG. 5B show the standard deviations of the measured resistance values. The Y-axis (resistance in Ω) is scaled logarithmically.

In the measurements a current sweep from 1 mA to 5 mA was applied. The resistance values were calculated from the measured voltage. The measurement was a two-point measurement on a wafer prober. Accordingly, the contact resistance of the needles used for contacting the test structure 500 is included in the measured resistance values.

In examples B2, B4, C2, C4, D2 and D3 the native oxide on the layer stack P1 was etched in situ with reactive H ion gas. Reactive H ion etching can be performed, e.g., as follows: In an etching chamber, after a stabilization of the gas flows for Ar and H₂, first the H₂ flow may be stopped. Subsequently, a medium wave (MF) plasma may be coupled in at a frequency of about 450 kHz via coils, through which an Ar plasma is ignited, for example.

Subsequently, reintroduction of H₂ gas produces H radicals in the Ar plasma. The H radicals are highly reactive and can reduce metal oxides and, e.g., silicon. This is used to chemically etch the native oxide 330 from the surface of the first interface metal layer IF1 (here, for example: the native oxide is TiO₂ which is etched from the Ti surface).

The process chamber for reactive H ion etching may be mounted directly in connection with the layer deposition chamber (e.g., sputtering system) for P2 layer stack deposition. Thus, the substrate 110 (e.g., wafer) can be transported directly to the layer deposition chamber after reactive H ion etching without vacuum interruption. There, the layer stack P2 is deposited.

Since (optional) reactive H ion etching and subsequent metal deposition to form the P2 layer stack may be performed in situ, native oxide does not grow again after chemical reactive H ion etching.

In contrast to in situ ion milling with argon ions (i.e., conventional back-sputtering), chemical reactive H ion etching is not capable of removing native oxide on aluminum. As apparent from the electrical resistance measurement results of FIG. 5B, an improvement in conductivity can be obtained by chemical reactive H ion etching (compare C1 with C2, C3 with C4, D1 with D2). However, the improvement in conductivity achieved by chemically reactive H ion etching alone may not be large enough to achieve resistivity values on the order of that of comparative example X.

Further, the measurement results show that low resistance values (e.g., lower than 10Ω) could only be obtained by the conventional sputter-etching process (example X) or by processes which include substrate annealing in combination with layer stack examples B and D, i.e. in the examples in which the native oxide layer 330 is sandwiched between two interface metal layers IF1, IF2. In example C, in which the P2 layer stack does not contain the second interface metal layer IF2, the resistance values remained significantly higher.

In other words, an IF1-330-IF2 interface followed by an annealing process yielded the best conductivity results (examples B3, B4, D3).

The annealing process may, e.g., be performed at a temperature between 300° C. and 500° C., in particular 350° C. and 450° C. Annealing may, e.g., be performed in a nitrogen atmosphere. A time period of annealing may, e.g., be equal to or greater than or less than 1 min, 10 min, 30 min, or 1 h.

On substrates 110 with aluminum metallization(s), annealing may, e.g., be carried out at about 450° C. for about 1 h (e.g., examples B3, B4, C3, C4 were processed that way). On substrates 110 including copper metallization(s), annealing may, e.g., be performed at about 400° C. for about 1 h. E.g., in example D3, copper was used in layer stack P2 and annealing was performed at 400° C. for about 1 h.

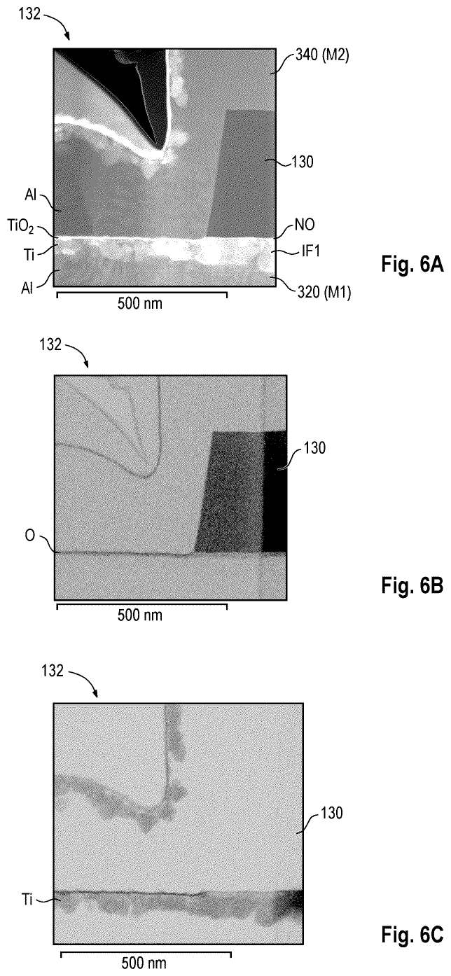

FIG. 6A is a TEM cross-section image of a bottom edge portion of a metal-filled contact hole 132 which has been produced according to example C4. That is, the contact hole 132 includes a Ti—O—Al interface and was subjected to chemical reactive H ion etching and annealing. As apparent from FIGS. 6B and 6C, showing the EDX analysis results for this contact hole 132, the titanium of the first interface metal layer IF1 (which had an initial thickness of 50 nm) significantly expanded by diffusion into the base metal layer 320 of aluminum (FIG. 6C). However, titanium of the first interface metal layer IF1 did not diffuse into aluminum of the top metal layer 340.

Referring to FIG. 6B, the native oxide layer 330 (corresponding to the O signal) can still be seen in FIG. 6B as a well-defined solid line. This is consistent with the electrical resistance measurements exhibiting a resistance of about 80Ω, i.e. more than ten times the electrical resistance measured for comparative example X.

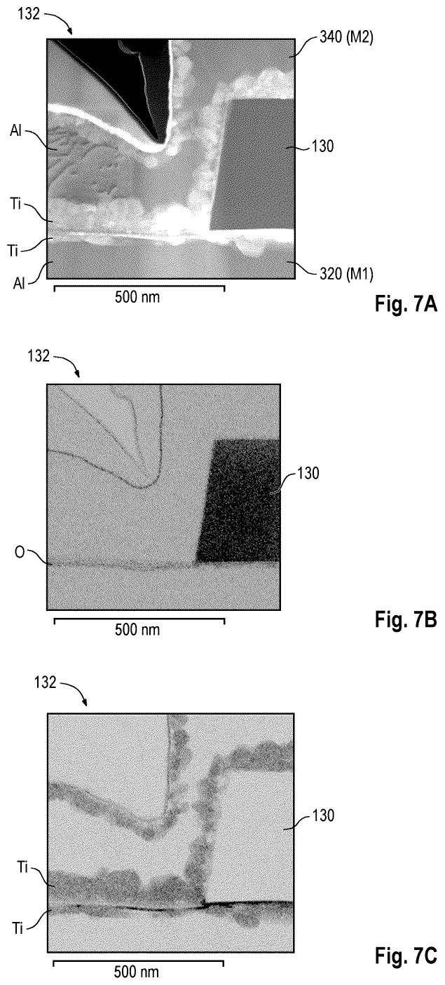

FIGS. 7A to 7C illustrate corresponding images for a metal-filled contact hole 132 fabricated according to example B4 of FIG. 5B. That is, a Ti—O—Ti interface was used, and the contact hole 132 was subjected to reactive H ion etching and annealing.

As apparent from FIG. 7C, the first and second interface metal layers IF1, IF2 (of Ti) each diffused into the adjacent base and top metal layers 320 and 340, respectively. Further, FIG. 7B illustrates that the oxygen signal O is considerably blurred compared to FIG. 6B. Apparently, the native oxide layer 330 was diluted and/or expanded by diffusion. Diffusion occurred in both directions along the axis of the contact hole 132.

The dilution/expansion of the native oxide layer 330 disintegrated or weakened the layer. This is consistent with the electrical resistance measurements exhibiting a low resistance of about 5Ω, i.e. similar to the electrical resistance measured for comparative example X (in which the native oxide had been removed). Differently stated, the native oxide was spread by diffusion (or “dissolved”) into the adjacent titanium layers IF1, IF2.

The expansion and/or dilution of the native oxide layer 330 may, e.g., be caused by diffusion of the native oxide (here: TiO₂) into the first and second interface metal layers IF1, IF2. Another process which may contribute to the expansion and/or dilution of the native oxide layer 330 could be that the metal of the first interface metal layer IF1 and the metal of the second interface metal layer IF2 diffuse into the native oxide layer 330.

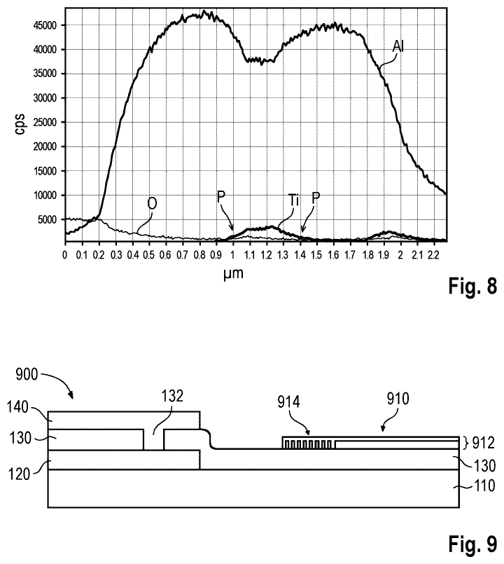

FIG. 8 illustrates a concentration profile of aluminum (Al), titanium (Ti), and oxygen (O) obtained by EDX analysis along a longitudinal cross-section of the metal-filled contact hole 132 of FIGS. 7A to 7C. The concentration profile of the first and second interface metal layers IF1, IF2 (Ti) is substantially expanded compared to the initial 2×50 nm=100 nm layer thickness. More specifically, the Ti concentration profile for example may have a thickness of equal to or greater than 200 nm or 300 nm. For example, this thickness (after diffusion) may be measured between points P of 20% of the peak concentration.

Differently stated, the first interface metal layer IF1 and the second interface metal layer IF2 may each be expanded by diffusion to provide a concentration profile which for example may have at 20% of the peak concentration at least twice the original layer thickness.

In FIG. 8, the native oxide layer 330 is expanded or diluted to an extent that is hardly visible in the diagram (compare the O signal).

Generally, the oxide layer 330 is diffusion-expanded. For example, the diffusion-expanded oxide layer 330 has an oxide concentration profile reaching into the first interface metal layer IF and into the second interface metal layer IF2. For example, the diffusion-expanded oxide layer 330 may, e.g., have a thickness of equal to or greater than 15 nm or 20 nm or 30 nm at 20% of its peak concentration. Differently stated, the diffusion-expanded oxide layer 330 may have a concentration profile which has at 20% of the peak concentration at least twice the original oxide layer thickness (here: about 10 nm of native oxide).

FIG. 9 illustrates an example of another micro-fabricated device 900. The micro-fabricated device 900 includes a metal-filled contact hole 132. Reference is made to the above description to avoid reiteration.

Further, the micro-fabricated device 900 comprises an optical active area 910 over the substrate 110. The optical active area 910 may, e.g., be disposed on or integrated in the dielectric layer 130.

The optical active area 910 may, e.g., include a waveguide 912 and/or an optical grating 914. Other optical elements such as, e.g., a mirror, a lens, etc. may also be included.

The micro-fabricated device 900 may, e.g., implement an ion trap or other micro-fabricated devices in which optical active areas 910 and metal layers interconnected by metal-filled contact holes 132 are implemented together. As mentioned above, conventional contact hole formation processes require sputter etching for native oxide removal, which affects the entire substrate 110 (e.g., wafer). In particular, optical elements may be degraded. Since sputter etching can be avoided according to the present disclosure, micro-fabricated devices 900 combining multi-layer metal wirings and optical elements may be easier to fabricate.

Alternatively or additionally, the micro-fabricated devices 100, 900 considered herein may implement “deep” metal-filled contact holes 132 having an aspect ratio of, e.g., equal to or greater than 3:1, 5:1 or 7:1. Since conventional sputter etching for oxide removal becomes increasingly ineffective as the aspect ratio increases, such micro-fabricated devices 100, 900 can be produced more easily by using the “oxide-dilution interface” in combination with annealing as described herein.

The following examples pertain to further aspects of the disclosure.

Example 1 is a method of generating a metal-filled contact hole in micro-fabrication technology includes forming a first metal layer over a substrate. A first interface metal layer is formed over the first metal layer, wherein the metal of the first interface metal layer is different from the metal of the first metal layer. A dielectric layer is formed over the first interface metal layer. A contact hole is formed in the dielectric layer. A second interface metal layer is formed over the first interface metal layer after forming the contact hole. A second metal layer is formed over the second interface metal layer, wherein the metal of the second interface metal layer is different from the metal of the second metal layer. The substrate is annealed, whereby an oxide layer that was formed on the first interface metal layer in a period between the formation of the first interface metal layer and the second interface metal layer is diluted by diffusion.

In Example 2, the subject matter of Example 1 can optionally include wherein the oxide layer is not subjected to a process of back-sputtering the oxide.

In Example 3, the subject matter of Example 1 or 2 can optionally include wherein the metal of the first interface metal layer is Ti or a Ti-based alloy.

In Example 4, the subject matter of any of the preceding Examples can optionally include wherein the metal of the second interface metal layer is Ti or a Ti-based alloy.

In Example 5, the subject matter of any preceding Example can optionally further include chemical reactive H ion etching of the oxide layer before forming the second interface metal layer.

In Example 6, the subject matter of Example 5 can optionally include wherein chemical reactive H ion etching is performed in situ with forming the second interface metal layer.

In Example 7, the subject matter of any preceding Example can optionally include wherein the metal of the first metal layer comprises Al, AlSiCu, AlCu or Cu.

In Example 8, the subject matter of any preceding Example can optionally include wherein the metal of the second metal layer comprises Al, AlSiCu, AlCu or Cu.

In Example 9, the subject matter of any preceding Example can optionally include wherein the layer thickness of the first interface metal layer and/or the layer thickness of the second interface metal layer is equal to or less than 100 nm, 80 nm, 60 nm or 40 nm before annealing.

In Example 10, the subject matter of any preceding Example can optionally include wherein the layer thickness of the oxide layer is equal to or less than 20 nm or 10 nm before annealing.

In Example 11, the subject matter of any preceding Example can optionally include wherein the annealing is performed such that the oxide layer is diluted by diffusion to provide a concentration profile which has at 20% of the peak concentration at least twice the original oxide layer thickness.

In Example 12, the subject matter of any preceding Example can optionally include wherein the annealing is performed such that the first interface metal layer and the second interface metal layer are each expanded by diffusion to provide a concentration profile which has at 20% of the peak concentration at least twice the original layer thickness of the first and second interface layers together.

In Example 13, the subject matter of any preceding Example can optionally include wherein the annealing is performed such that an electrical resistance of the metal-filled contact hole is reduced by a factor of equal to or greater than 10, 20 or 50 compared to the electrical resistance of the metal-filled contact hole without annealing.

In Example 14, the subject matter of any preceding Example can optionally include wherein the annealing is performed at a temperature between 300° C. and 500° C., in particular 350° C. and 450° C.

Example 15 is a method of manufacturing a micro-fabricated device comprises providing a wafer substrate; forming alternating metal layers and dielectric layers over the wafer substrate; generating a plurality of metal-filled contact holes between at least two metal layers separated by at least one dielectric layer according to the method recited above; and dicing the wafer substrate to singulate the micro-fabricated device.

In Example 16, the subject matter of Example 15 can optionally include wherein the wafer substrate is a semiconductor wafer substrate, the method further comprises processing the semiconductor wafer substrate to generate integrated circuits in the semiconductor wafer substrate, wherein at least some of the metal layers serve as wiring layers for the integrated circuits.

In Example 17, the subject matter of Example 15 or 16 can optionally further include forming an optical active area over the wafer substrate, the optical active area being exposed after forming the contact holes in the dielectric layer.

Example 18 is a micro-fabricated device including a substrate; a first metal layer disposed over the substrate; a first interface metal layer disposed over the first metal layer, wherein the metal of the first interface metal layer is different from the metal of the first metal layer; a dielectric layer disposed over the first interface metal layer; a contact hole in the dielectric layer; a second metal layer disposed over the dielectric layer and reaching into the contact hole, wherein, in the contact hole, a second interface metal layer is disposed over the first interface metal layer, wherein the metal of the second interface metal layer is different from the metal of the second metal layer; and a diffusion-diluted oxide layer located between the first interface metal layer and the second interface metal layer.

In Example 19, the subject matter of Example 18 can optionally include wherein the diffusion-diluted oxide layer has an oxide concentration profile reaching into the first interface metal layer and into the second interface metal layer.

In Example 20, the subject matter of Example 18 or 19 can optionally include wherein the first interface metal layer and the second interface metal layer each have a diffusion-diluted metal concentration profile.

In Example 21, the subject matter of Example 20 can optionally include wherein a concentration profile of the metal of the first interface metal layer and the metal of the second interface metal layer has a thickness of equal to or greater than 200 nm or 300 nm at 20% of the peak concentration.

In Example 21, the subject matter of Example 20 can optionally include wherein the functional layer is a metal layer or an inorganic dielectric layer or a semiconductor layer.

In Example 22, the subject matter of any Example 18 to 21 can optionally include wherein the first interface metal layer and/or the second interface metal layer is Ti or a Ti-based alloy.

In Example 23, the subject matter of any Example 18 to 22 can optionally include wherein the metal of the first metal layer and/or the metal of the second metal layer comprises Al, AlSiCu, AlCu or Cu.

In Example 24, the subject matter of any Example 18 to 23 can optionally include wherein the substrate comprises a semiconductor material, sapphire, or glass.

In Example 25, the subject matter of any Example 18 to 23 can optionally include wherein the substrate comprises a semiconductor material, an integrated circuit is provided in the semiconductor material, and at least some of the metal layers serve as wiring layers for the integrated circuit.

In Example 26, the subject matter of any Example 18 to 25 can optionally further include an optical active area over the substrate.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of generating a metal-filled contact hole in micro-fabrication technology, the method comprising:
forming a first metal layer over a substrate;
forming a first interface metal layer over the first metal layer, wherein a metal of the first interface metal layer is different from a metal of the first metal layer;
forming a dielectric layer over the first interface metal layer;
forming a contact hole in the dielectric layer;
forming a second interface metal layer over the first interface metal layer after forming the contact hole;
forming a second metal layer over the second interface metal layer, wherein a metal of the second interface metal layer is different from a metal of the second metal layer; and
annealing the substrate, such that an oxide layer previously formed on the first interface metal layer in a period between the formation of the first interface metal layer and the second interface metal layer is diluted by diffusion.

2. The method of claim 1, wherein the oxide layer is not subjected to a process of back-sputtering the oxide.

3. The method of claim 1, wherein the metal of the first interface metal layer is Ti or a Ti-based alloy.

4. The method of claim 1, wherein the metal of the second interface metal layer is Ti or a Ti-based alloy.

5. The method of claim 1, further comprising:
chemical reactive H ion etching of the oxide layer before forming the second interface metal layer.

6. The method of claim 5, wherein the chemical reactive H ion etching is performed in situ with forming the second interface metal layer.

7. The method of claim 1, wherein the metal of the first metal layer comprises Al, AlSiCu, AlCu or Cu.

8. The method of claim 1, wherein the metal of the second metal layer comprises Al, AlSiCu, AlCu or Cu.

9. The method of claim 1, wherein a layer thickness of the first interface metal layer and/or a layer thickness of the second interface metal layer is equal to or less than 100 nm, 80 nm, 60 nm or 40 nm before the annealing.

10. The method of claim 1, wherein a layer thickness of the oxide layer is equal to or less than 20 nm or 10 nm before the annealing.

11. The method of claim 1, wherein the annealing is performed such that the oxide layer is diluted by diffusion to provide a concentration profile which has at 20% of the peak concentration at least twice the original oxide layer thickness.

12. The method of claim 1, wherein the annealing is performed such that the first interface metal layer and the second interface metal layer are each expanded by diffusion to provide a concentration profile which has at 20% of the peak concentration at least twice the original layer thickness of the first and second interface layers together.

13. The method of claim 1, wherein the annealing is performed such that an electrical resistance of the metal-filled contact hole is reduced by a factor of equal to or greater than 10, 20 or 50 compared to the electrical resistance of the metal-filled contact hole without annealing.

14. The method of claim 1, wherein the annealing is performed at a temperature between 300° C. and 500° C.

15. A method of manufacturing a micro-fabricated device, the method comprising:
providing a wafer substrate;
forming alternating metal layers and dielectric layers over the wafer substrate;
generating a plurality of metal-filled contact holes between at least two metal layers separated by at least one dielectric layer according to the method of claim 1; and
dicing the wafer substrate to singulate the micro-fabricated device.

16. The method of claim 15, wherein the wafer substrate is a semiconductor wafer substrate, the method further comprising:
processing the semiconductor wafer substrate to generate integrated circuits in the semiconductor wafer substrate, wherein at least some of the metal layers serve as wiring layers for the integrated circuits.

17. The method of claim 15, further comprising:
forming an optical active area over the wafer substrate, the optical active area being exposed after forming the contact holes in the dielectric layer.

18. A micro-fabricated device, comprising:
a substrate;
a first metal layer disposed over the substrate;
a first interface metal layer disposed over the first metal layer, wherein a metal of the first interface metal layer is different from a metal of the first metal layer;
a dielectric layer disposed over the first interface metal layer;
a contact hole in the dielectric layer;
a second metal layer disposed over the dielectric layer, wherein in the contact hole, a second interface metal layer is disposed over the first interface metal layer, wherein the second metal layer is electrically connected to the second interface metal layer and a metal of the second interface metal layer is different from a metal of the second metal layer; and
a diffusion-diluted oxide layer located between the first interface metal layer and the second interface metal layer.

19. The micro-fabricated device of claim 18, wherein the diffusion-diluted oxide layer has an oxide concentration profile reaching into the first interface metal layer and into the second interface metal layer.

20. The micro-fabricated device of claim 18, wherein the first interface metal layer and the second interface metal layer each have a diffusion-diluted metal concentration profile.

21. The micro-fabricated device of claim 20, wherein a concentration profile of the metal of the first interface metal layer and the metal of the second interface metal layer has a thickness of equal to or greater than 200 nm or 300 nm at 20% of the peak concentration.

22. The micro-fabricated device of claim 18, wherein the first interface metal layer and/or the second interface metal layer is Ti or a Ti-based alloy.

23. The micro-fabricated device of claim 18, wherein the metal of the first metal layer and/or the metal of the second metal layer comprises Al, AlSiCu, AlCu or Cu.

24. The micro-fabricated device of claim 18, wherein the substrate comprises a semiconductor material, sapphire, or glass.

25. The micro-fabricated device of claim 18, wherein the substrate comprises a semiconductor material, an integrated circuit is provided in the semiconductor material, and at least some of the metal layers serve as wiring layers for the integrated circuit.

26. The micro-fabricated device of claim 18, further comprising:
an optical active area over the substrate.
